(19) United States
(12) Patent Application Publication
(10) Pub. No.: US 2021/0375732 A1
(43) Pub. Date: Dec. 2, 2021

(54) PARTIAL COMPONENT EMBEDDING IN A SUBSTRATE

(71) Applicant: QUALCOMM Incorporated, San Diego, CA (US)

(72) Inventors: Paragkumar Ajaybhai THADESAR, San Diego, CA (US); Sameer Sunil VADHAVKAR, San Diego, CA (US); Francesco CARRARA, San Diego, CA (US); Daniel Daeik KIM, San Diego, CA (US)

(21) Appl. No.: 16/890,376

(22) Filed: Jun. 2, 2020

(51) Int. Cl. H01L 23/498; H01L 21/56; H01L 23/31; H01L 21/48

(52) U.S. Cl. CPC H01L 23/49805; H01L 21/4846; H01L 23/3157; H01L 21/565

(57) ABSTRACT

Certain aspects of the present disclosure generally relate to a dielectric removal methodology and a metal patterning approach to allow partial embedding of electronic components (e.g., surface mount devices (SMDs)) in a substrate. By partially embedding relatively taller SMDs, the overall height of an electronic device may be reduced.

### BACKGROUND

### Field of the Disclosure

Certain aspects of the present disclosure generally relate to electronic components and, more particularly, to partially embedding surface-mount components in a substrate.

### Description of Related Art

A continued emphasis in semiconductor technology is to create improved performance semiconductor devices at competitive prices. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

Surface-mount technology (SMT) is a method in which the components are mounted or placed directly onto the surface of a substrate or printed circuit board (PCB). An electronic device so made is called a surface-mount device (SMD). In industry, SMT has largely replaced the through-hole technology construction method of fitting components with wire leads into holes in the circuit board. Both technologies can be used on the same board, with the through-hole technology used for components not suitable for surface mounting such as large transformers and power semiconductors implemented with heat sinks. An SMD may have short pins or leads of various styles, flat contacts, a matrix of solder balls (e.g., a ball grid array (BGA)), or terminations on the body of the component.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include decreased height of electronic apparatus, such as radio frequency (RF) modules.

Certain aspects of the present disclosure generally relate to a prepreg removal methodology and a metal patterning approach to allow partial embedding of surface-mount components in substrates.

Certain aspects of the present disclosure provide an electronic device. The electronic device generally includes a substrate comprising a plurality of metal layers separated by one or more dielectric layers, the substrate having a cavity with a depth from an upper surface of the substrate to a first metal layer in the plurality of metal layers that is beneath a topmost metal layer in the plurality of metal layers, wherein at least a portion of a dielectric layer is disposed above the first metal layer in the cavity and wherein the at least the portion of the dielectric layer has one or more openings. The electronic device further includes a surface mount component disposed in the cavity above the at least the portion of the dielectric layer disposed above the first metal layer, wherein each of one or more terminals of the surface mount component is affixed with solder to the first metal layer via the one or more openings in the at least the portion of the dielectric layer and wherein the surface mount component is at least partially embedded in the substrate.

Certain aspects of the present disclosure are directed to a method for fabricating an electronic device. The method generally includes removing a portion of a substrate comprising a plurality of metal layers separated by one or more dielectric layers to form a cavity and expose a portion of a first metal layer in the plurality of metal layers that is beneath a topmost metal layer in the plurality of metal layers, wherein the removing leaves at least a portion of a dielectric layer disposed above the first metal layer in the cavity, the at least the portion of the dielectric layer having one or more openings, and depositing a solder paste in the one or more openings in the at least the portion of the dielectric layer. The method further includes disposing a surface mount component in the cavity, such that at least a portion of each of one or more terminals of the surface mount component is aligned with the solder paste in the one or more openings, and heating the solder paste, such that the surface mount component is affixed to the first metal layer and is at least partially embedded in the substrate.

Certain aspects of the present disclosure are directed to a method for fabricating an electronic device. The method generally includes removing a portion of a substrate comprising a plurality of metal layers separated by one or more dielectric layers to form a cavity and expose a lateral surface of a first metal layer in the plurality of metal layers, and depositing a solder paste above the first metal layer adjacent to the cavity. The method further includes disposing a surface mount component in the cavity, such that at least a portion of each of one or more terminals of the surface mount component is aligned with the solder paste above the first metal layer, and heating the solder paste, such that the surface mount component is affixed to the first metal layer and is at least partially embedded in the substrate.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a cross-sectional view of an example chip package having a surface mount device (SMD) disposed on a land side of a substrate, in accordance with certain aspects of the present disclosure.

FIG. 2A is a cross-sectional view of an example electronic device with an SMD disposed on a surface of a substrate.

FIGS. 2B-2H are cross-sectional views of example electronic devices with different implementations of a partially embedded SMD, in accordance with certain aspects of the present disclosure.

FIG. 3A is a top view of the electronic device of FIG. 2F through the topmost metal layer with certain features removed, in accordance with certain aspects of the present disclosure.

FIG. 3B is a top view of the electronic device of FIG. 2G through the topmost metal layer with certain features removed, in accordance with certain aspects of the present disclosure.

FIGS. 4A-4E illustrate example fabrication operations to build an electronic device with a partially embedded SMD, in accordance with certain aspects of the present disclosure.

FIG. 5 is a flow diagram of an example process to fabricate an electronic device with a partially embedded SMD, in accordance with certain aspects of the present disclosure.

FIG. 6 is a flow diagram of an example process to fabricate an electronic device with a partially embedded SMD and peripheral metal contacts, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to a dielectric (e.g., prepreg) removal methodology and a metal patterning approach to allow partial embedding of electronic components (e.g., surface mount devices (SMDs)) in a substrate. By partially embedding relatively taller SMDs, the overall height of an electronic device may be reduced.

### Example Chip Package with a SMD

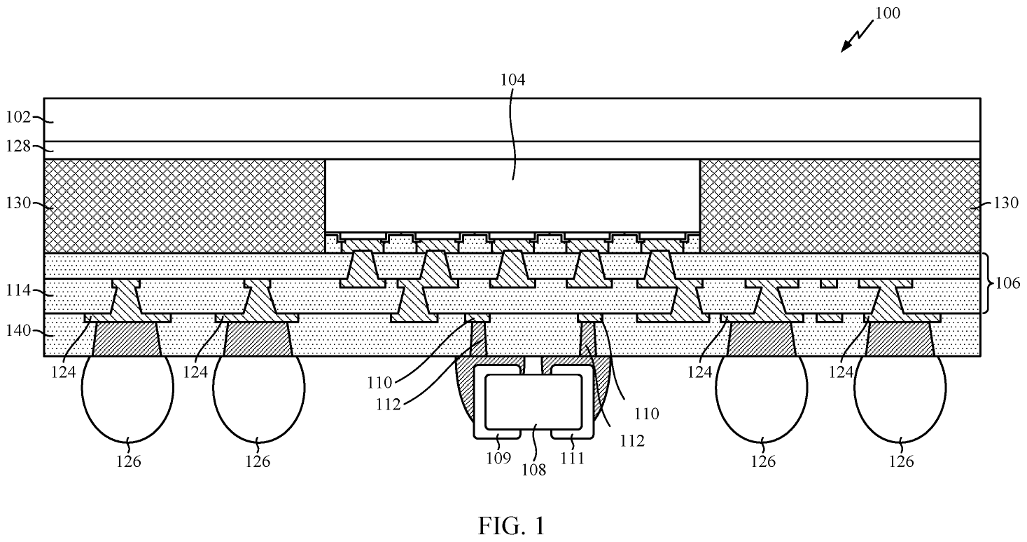

FIG. 1 is a cross-sectional view of an example chip package 100, in accordance with certain aspects of the present disclosure. As shown, the chip package 100 may include a chip carrier 102, an integrated circuit (IC) die 104, one or more redistribution layers 106, an electrical component 108, conductive pads 110, and at least one conductive via 112. The chip package 100 may be, for example, a fan-out wafer-level package.

The conductive pads 110 may be disposed on a layer 114 of the one or more redistribution layers 106. In certain aspects, the layer 114 may be a dielectric layer of the one or more redistribution layers 106. A layer of solder resist 140 may be disposed below the one or more redistribution layers 106.

One of the conductive pads 110 may couple to a first terminal 109 of the electrical component 108, and another one of conductive pads 110 may couple to a second terminal 111 of the electrical component 108. For certain aspects, one or more vias 112 may be routed between the conductive pads 110 and the terminals 109, 111 of the electrical component 108. In certain aspects, the conductive pads 110 may be coupled to a power supply voltage rail (e.g., Vdd and electrical ground) and may be electrically isolated from one another.

The electrical component 108 may be a surface-mount electrical device (e.g., a surface mount device (SMD)) coupled to the chip package 100 on the land side of the redistribution layers 106, as illustrated. For instance, the electrical component 108 may be a passive surface-mount electrical device such as a capacitor, inductor, or resistor. Although only one land-side electrical component is depicted in FIG. 1, it is to be understood that there may be zero or more than one land-side electrical component. Additionally or alternatively, one or more other electrical components may be disposed on the die side of the redistribution layers 106. The electrical component(s) disposed on the die side may be shorter or taller than the die 104.

Under bump conductors 124 (e.g., under bump metallization (UBM) pads) may be disposed on the same layer 114 as the conductive pads 110. In certain aspects, the conductive vias 112 may provide fan-out connections to the under bump conductors 124. Solder bumps 126 may be disposed below the under bump conductors 124. The solder bumps 126 may enable the chip package 100 to be mounted to external circuitry, such as a circuit board or another chip or wafer.

The chip package 100 may also include a conductive layer 128 disposed between the die 104 and the chip carrier 102. The conductive layer 128 may act as conductive shielding, such as a ground plane or a conductive foil (e.g., copper foil). In certain aspects, the conductive layer 128 may be a heat spreader that dissipates heat from the die 104.

The chip carrier 102 may provide a structure for packaging the die 104 at the wafer level and post-fabrication. The chip carrier 102 may be, for example, a glass carrier or silicon carrier. The chip carrier 102 may be removed or thinned after fabricating the chip package 100. The die 104 may be encapsulated in the chip package 100 by a molding compound 130. The molding compound 130 may be an epoxy resin, for example. For certain aspects, the chip carrier and/or the conductive layer 128 may be eliminated from the chip package 100. In this case, the molding compound 130 may have a height extending above the height of the die 104, especially if there are electrical components 108 and/or other die disposed on the die side of the redistribution layers 106 that are taller than the height of the die 104.

### Example Electronic Device with SMDs

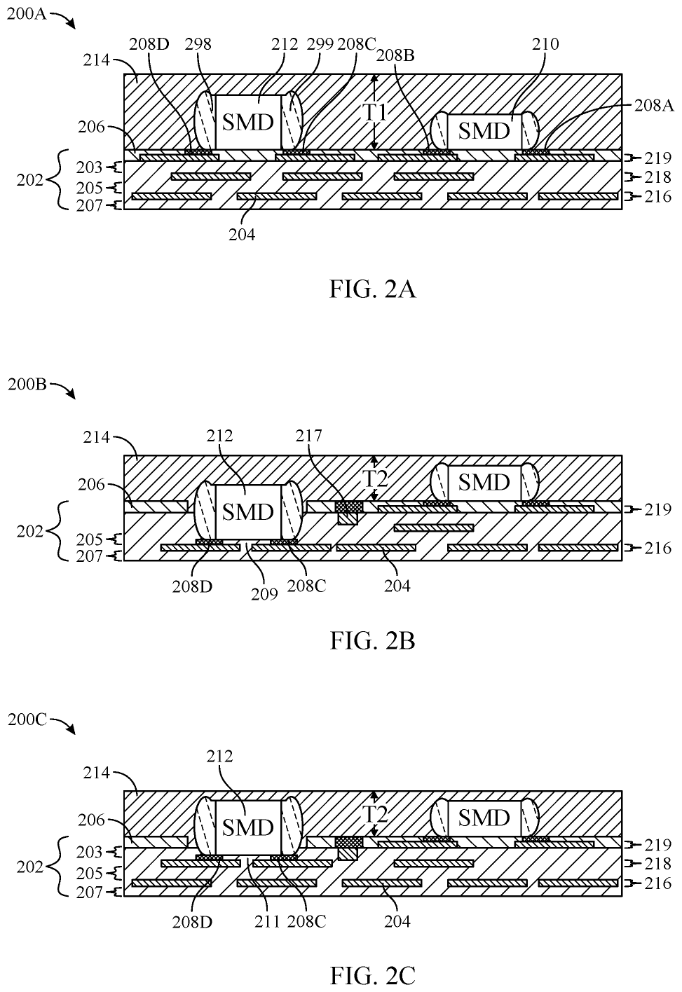

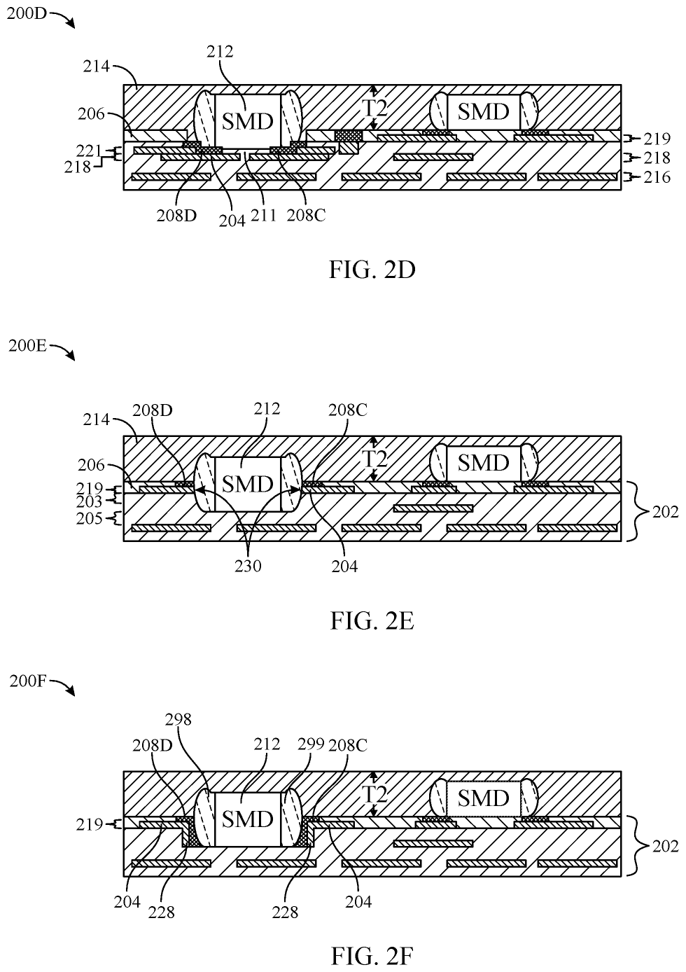

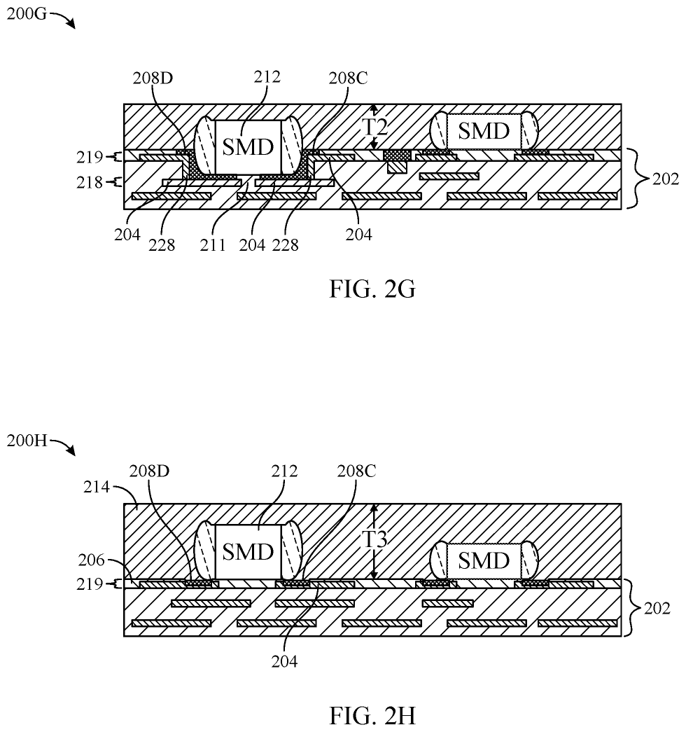

In certain electronic devices, such as 5^{th} generation (5G) radio frequency (RF) modules, SMD components of various geometries and heights may be used. SMDs may include passive components (e.g., capacitors, inductors, and resistors) and/or active components (transistors, diodes, integrated circuits (ICs), etc.). Regarding the height of SMDs, some SMDs (e.g., 0201 SMDs) may be as tall as 350-400 μm. Conventionally, SMD components are coupled directly on a surface of a substrate, as further described herein with respect to FIG. 2A, such that the height of the electronic device is at least the sum of the heights of the substrate and the tallest SMD component, which may narrow the scope of implementation for the electronic device. More specifically, an SMD having a large height relative to the rest of a device in which the SMD is implemented may significantly increase the overall device thickness. A device with increased thickness may have limited potential applications. With conventional techniques, embedding relatively tall SMD components in a substrate in a size-efficient manner may be difficult, since many substrates used in such electronic devices with SMDs are generally thin.

FIG. 2A depicts a cross-sectional view of an electronic device 200A. The electronic device 200A may include a substrate 202, such as a laminate substrate, which may have or may lack a core. The substrate 202 may include a plurality of metal layers 216, 218, 219 and a plurality of dielectric layers 203, 205, 207 separating the metal layers, as shown. The metal layers may include conductive elements 204, such as traces, planes, and/or pads. Although only three metal layers 216, 218, 219 are shown, it is to be understood that the substrate 202 may include more or less than three metal layers. Vias may be used to connect various conductive elements on different metal layers. The dielectric layers 203, 205, 207 may be composed of epoxy (e.g., prepreg, such as FR4), resin (e.g., bismaleimide-triazine (BT)), or another suitable material. The conductive elements 204 may be composed of copper, silver, gold, aluminum, or any other suitable material.

In certain aspects, the electronic device 200A may include a solder resist layer 206 covering at least a portion of some of the conductive elements 204 in an outer metal layer (e.g., the topmost metal layer 219) designated for additional components (e.g., SMDs and/or solder balls) to be added. The solder resist layer 206 may be electrically insulative and may act as a stencil for solder paste to be added in various cavities of the solder resist layer above particular conductive elements 204 (e.g., conductive pads). When reflowed, the solder paste, becomes solder areas 208A, 208B, 208C, 208D (collectively referred to as “solder areas 208”). The reflowed solder areas 208 may electrically and mechanically couple electrical components, such as a small SMD 210 and a large SMD 212, to the conductive elements 204. For example, the small SMD 210 may be disposed above the solder resist layer 206 and have terminals aligned with the solder area 208A and the solder area 208B. Furthermore, the large SMD 212 may be disposed above the solder resist layer 206 and have terminals 298, 299 aligned with the solder area 208C and the solder area 208D.

In certain aspects, the small SMD 210, the large SMD 212, and the substrate 202 may be covered by an encapsulation material 214 (e.g., a molding compound) disposed above the substrate 202. The encapsulation material 214 may have a height T1. For example, height T1 may be 400-500 μm. In certain aspects, the height of the substrate 202 may be 200-300 μm, and the height of the large SMD 212 may be 350-400 μm.

As described above, the implementation of the large SMD 212 directly on top of the substrate 202 may lead to increased height of the electronic device 200A and a narrowed scope of potential applications. Accordingly, certain aspects of the present disclosure relate to a dielectric (e.g., prepreg) removal methodology and a metal patterning approach to allow partial embedding of electronic components, such as SMDs, in the substrate. In this manner, electronic devices may have reduced height, and component embedding may be easier than with conventional techniques.

### Example Electronic Devices with a Partially Embedded SMD

According to certain aspects of the present disclosure, SMDs may be partially embedded above and/or below the substrate (i.e., on either or both the die side and the land side of the substrate). However, for ease of understanding, the examples provided below show and describe the SMD being partially embedded above the substrate. The reader is to understand that this SMD or one or more SMDs may alternatively or additionally be partially embedded below the substrate.

FIG. 2B depicts a cross-sectional view of an electronic device 200B with a partially embedded SMD (e.g., the large SMD 212), in accordance with certain aspects of the present disclosure. In certain aspects, electronic device 200B may be generally similar in construction when compared to electronic device 200A. However, the large SMD 212 may be partially embedded in the substrate 202. Accordingly, a portion of the substrate 202 (e.g., a portion of one or more metal layers and/or a portion of one or more dielectric layers) may be selectively removed (e.g., etched away or removed by laser) to form a cavity for the large SMD 212 to be partially inserted into the substrate 202. For certain aspects, in comparison to electronic device 200A, the substrate 202 may further include one or more alignment vias, such as alignment via 217, and portions of the solder resist layer 206 may be removed (e.g., etched) to expose the alignment via 217 and/or an area for the cavity. As described above, the height of the substrate 202 may be 200-300 μm, and the height of the large SMD 212 may be 350-400 μm, for example. The cavity of the substrate 202 into which the large SMD 212 may be partially inserted may be as deep as 200 μm, for example.

The large SMD 212 may be disposed above a remaining portion 209 of the dielectric layer 205 in the cavity. The remaining portion 209 of the dielectric layer 205 in the cavity may have one or more holes, and solder paste may be disposed in the holes, such that the remaining portion of the dielectric layer acts as a stencil for the application of solder paste. As shown, the large SMD 212 may have terminals 298, 299 aligned with the solder area 208D and the solder area 208C above conductive elements 204 in the bottommost metal layer 216. Furthermore, the partial insertion of the large SMD 212 into the substrate 202 may allow the encapsulation material 214 to have a height T2 less than the height T1 of FIG. 2A. For example, height T2 may be 250-350 μm. Although the large SMD 212 has been coupled to the bottommost metal layer 216 in the multi-layer embedding portrayed in FIG. 2B, portions of fewer metal layers may be removed to construct the cavity for the SMD.

For example, FIG. 2C depicts a cross-sectional view of an electronic device 200C with the large SMD 212 being partially embedded in the substrate 202 at the metal layer 218, in accordance with certain aspects of the present disclosure. In certain aspects, electronic device 200C may be generally similar in construction when compared to electronic device 200B of FIG. 2B. However, the large SMD 212 of electronic device 200B may be partially embedded into the substrate 202 above the metal layer 218, one metal layer down from the topmost metal layer 219. Thus, this may be referred to as “single-layer embedding,” due to the large SMD 212 being lowered from the topmost metal layer 219 to the next lower metal layer 218. Compared to the electronic device 200B, a smaller portion of the substrate 202 in the electronic device 200C may be selectively removed (e.g., etched away) to form a cavity for the large SMD 212 to be inserted. The large SMD 212 may be disposed above a remaining portion 211 of the dielectric layer 203 in the cavity. The remaining portion 211 of the dielectric layer 203 in the cavity may have one or more holes, and solder paste may be disposed in the holes, such that the remaining portion of the dielectric layer acts as a stencil for the application of solder paste. In the electronic device 200C, the encapsulation material 214 may have the same height T2 (<T1) or a slightly larger height T3 (not shown, but also lower than T1).

FIG. 2D depicts a cross-sectional view of an electronic device 200D with the large SMD 212 having terminals 298, 299 coupled to stepped metal structures, in accordance with certain aspects of the present disclosure. In certain aspects, electronic device 200D may be generally similar in construction when compared to electronic device 200C. However, the substrate 202 may include one or more additional metal layers 221 disposed between the topmost metal layer 219 and the bottommost metal layer 216. The one or more intermediate metal layers may have conductive elements 204 that may be stacked above the conductive elements of one of the metal layers (e.g., above metal layer 218) to form the stepped metal structures, as shown, such as in the cavity. In other words, there can be two or more metal layers involved in forming the stepped structure. The solder areas 208C, 208D may also be step-shaped and may conform to the shape of the stacked conductive elements forming the stepped metal structures, as illustrated in FIG. 2D. Upper portions of the stacked conductive elements may be covered by dielectric material of the dielectric layers or may be exposed. For example, the remaining portion 211 of the dielectric layer 203 in the cavity may cover part of the conductive elements 204 in metal layer 218 in the stepped metal structure, and other portions of dielectric layer 203 may cover part of the conductive elements 204 in metal layer 221 in the stepped metal structure. Moreover, the solder areas 208C, 208D may cover part of the conductive elements 204 in metal layer 218 and part of the conductive elements 204 in metal layer 221. Similar to the electronic device 200C of FIG. 2C, the encapsulation material 214 in the electronic device 200D of FIG. 2D may have a height T2 (or T3)<T1.

FIG. 2E depicts a cross-sectional view of an electronic device 200E with peripheral horizontal metal contacts for connections with the terminals of an SMD, in accordance with certain aspects of the present disclosure. In certain aspects, electronic device 200E may be generally similar in construction when compared to electronic device 200B. However, a lateral surface of each of the terminals of the SMD (e.g., large SMD 212) may be coupled horizontally to a peripheral metal contact, as opposed to a bottom surface of each of the terminals being coupled vertically to a conductive element beneath the terminal. The peripheral metal contacts may comprise lateral surfaces 230 of conductive elements 204 in one or more of the metal layers exposed by the cavity, such as the topmost metal layer 219 (as shown) and/or another lower metal layer (e.g., metal layer 218). Solder paste may be disposed above the peripheral metal contacts and reflowed to form solder areas 208C, 208D at peripheral portions of the large SMD 212, as shown. For example, the large SMD 212 may be partially embedded in a portion of the substrate 202, but the lateral surfaces of the terminals 298, 299 of the large SMD 212 may be aligned with the solder areas 208C, 208D disposed above the conductive elements 204 in the topmost metal layer 219. Furthermore, the SMD (e.g., large SMD 212) may be disposed in a cavity in which no metal layer is exposed at the bottom of the cavity. In other words, the SMD may be disposed above a remaining portion of a dielectric layer (e.g., dielectric layer 205, dielectric layer 203, or a dielectric material in metal layer 218). The encapsulation material 214 in the electronic device 200E may have a height T2 (or T3)<T1, as shown.

FIG. 2F depicts a cross-sectional view of an electronic device 200F with L-shaped metal contacts for peripheral horizontal and vertical connections with the terminals of an SMD, in accordance with certain aspects of the present disclosure. In certain aspects, electronic device 200F may be generally similar in construction when compared to electronic device 200E. However, the electronic device 200E may have a cavity with one or more rows of vias 228 (e.g., on either or both sides of the cavity). Each row of vias 228 may be coupled to a conductive element 204 on a metal layer (e.g., the topmost metal layer 219) above or below the row(s) of vias, thereby forming an L-shaped conductive contact. Solder paste applied above the L-shaped conductive contacts may self-align due to the solder paste attaching to metal tops and sides of the contacts. When the solder paste is reflowed, L-shaped solder areas 208C, 208D may be formed adjacent to portions of the L-shaped conductive contacts. In this manner, substantial lateral surfaces of the terminals 298, 299 of the large SMD 212 may be coupled to the L-shaped contacts through the L-shaped solder areas 208C, 208D. In certain aspects, the angle of the vias 228 with respect to a conductive element 204 may be a right angle, while in other aspects the angle of the vias may be obtuse or acute. As shown, the encapsulation material 214 in the electronic device 200F may have a height T2 (or T3)<T1.

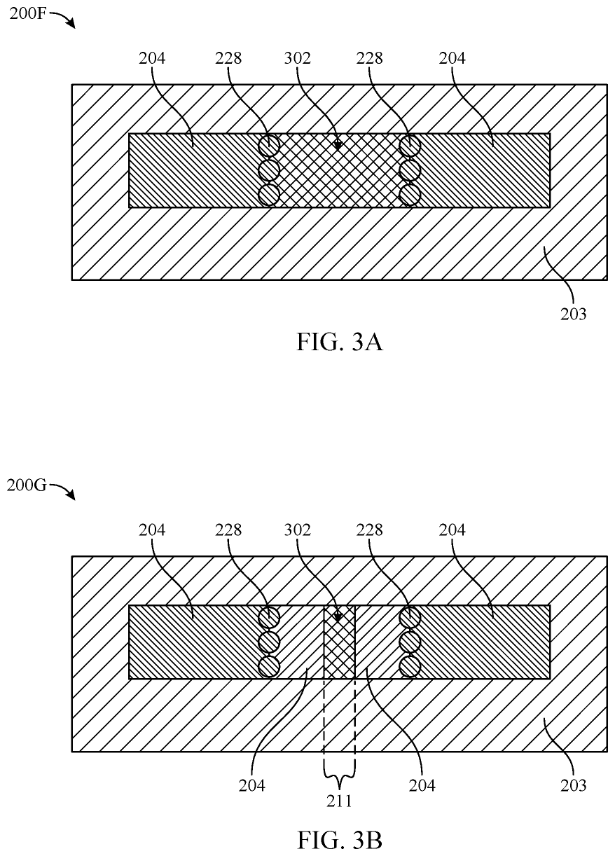

FIG. 3A depicts a top view of the electronic device 200F through the topmost metal layer 219 with the large SMD 212 and solder areas removed. Electronic device 200F may include a cavity 302 for receiving the large SMD 212. The cavity 302 may be formed by selectively etching the substrate 202, as described below. In certain aspects, the vias in the rows of vias 228 may be left as full columns, as illustrated in FIG. 3A. In other aspects, the vias in the rows of vias 228 may have portions removed, for example, due to the removal process to form the cavity 302.

FIG. 2G depicts a cross-sectional view of an electronic device 200G with peripheral conformal contacts for horizontal and vertical connections with the terminals of an SMD, in accordance with certain aspects of the present disclosure. In certain aspects, electronic device 200G may be generally similar in construction when compared to electronic device 200F. However, the row(s) of vias 228 in the cavity may connect conductive elements 204 in two adjacent metal layers (e.g., metal layers 218, 219), both above and below the vias, thereby forming stepped metal structures, instead of L-shaped structures. Solder paste applied above the stepped structures may self-align due to the solder paste attaching to metal tops and sides of the contacts, conforming to the shaped of the stepped metal structures. When the solder paste is reflowed, generally step-shaped solder areas 208C, 208D may be formed adjacent to portions of the stepped metal structures. In this manner, substantial lateral and bottom surfaces of the terminals 298, 299 of the large SMD 212 may be coupled to the stepped structures through the generally step-shaped solder areas 208C, 208D. Upper portions of the conductive elements 204 in the stepped metal structures may be covered by the solder resist layer 206, may be covered by dielectric material of the dielectric layers, or may be exposed. For example, the remaining portion 211 of the dielectric layer 203 in the cavity may cover part of the conductive elements 204 in metal layer 218 in the stepped metal structure, and the solder resist layer 206 may cover part of the conductive elements 204 in metal layer 219 in the stepped metal structure. Moreover, the solder areas 208C, 208D may cover part of the conductive elements 204 in metal layer 218 and part of the conductive elements 204 in metal layer 219. As shown, the encapsulation material 214 in the electronic device 200G may have a height T2 (or T3)<T1.

FIG. 3B depicts a top view of the electronic device 200G through the topmost metal layer 219 with the large SMD 212 and solder areas removed. The cavity 302 may be formed by selectively etching the substrate 202, as described below. In certain aspects, the vias in the rows of vias 228 may be left as full columns, as illustrated in FIG. 3B. In other aspects, the vias in the rows of vias 228 may have portions removed, for example, due to the removal process to form the cavity 302.

FIG. 2H depicts a cross-sectional view of an electronic device 200H having a substrate with a thinner solder resist layer 206 and one where certain conductive elements 204 have cavities for disposal of solder paste therein, in accordance with certain aspects of the present disclosure. In certain aspects, electronic device 200H may be generally similar in construction when compared to electronic device 200A of FIG. 2A. However, conductive elements 204 in the topmost metal layer 219 for connection to terminals of one or more SMDs may be selectively etched to form cavities in the conductive elements. For instance, the depth of these cavities may be 10-15 μm. These cavities in the conductive elements 204 may be filled with solder paste, using the solder resist layer 206 as a stencil, for example. The terminals of the SMDs (e.g., SMDs 210, 212) may be disposed above the solder paste disposed in the cavities of the conductive elements 204, and the solder paste may be reflowed to form the solder areas for electrically and mechanically coupling the terminals of the SMDs to the conductive elements. In this manner and with a thinner solder resist layer 206, the height of the SMDs above the topmost metal layer in the electronic device 200H may be less than the height of the SMDs above the topmost metal layer in the electronic device 200A of FIG. 2A, thereby potentially lowering the overall height of the electronic device. In this case, the encapsulation material 214 may have a height T3, as shown. In certain aspects, the height T3 may be less than the height T1 of electronic device 200A, but greater than height T2 of electronic devices 200B-200G.

### Example Fabrication Processes

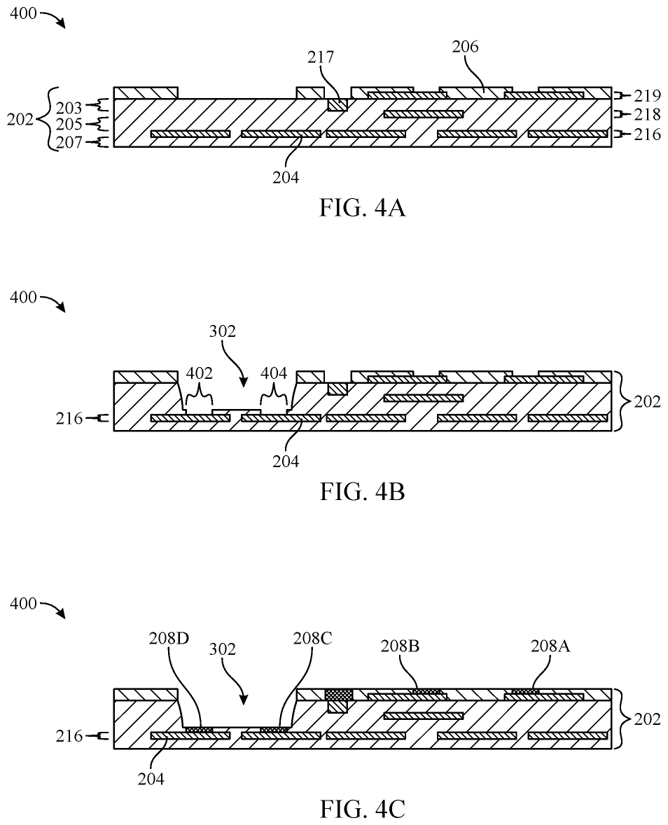

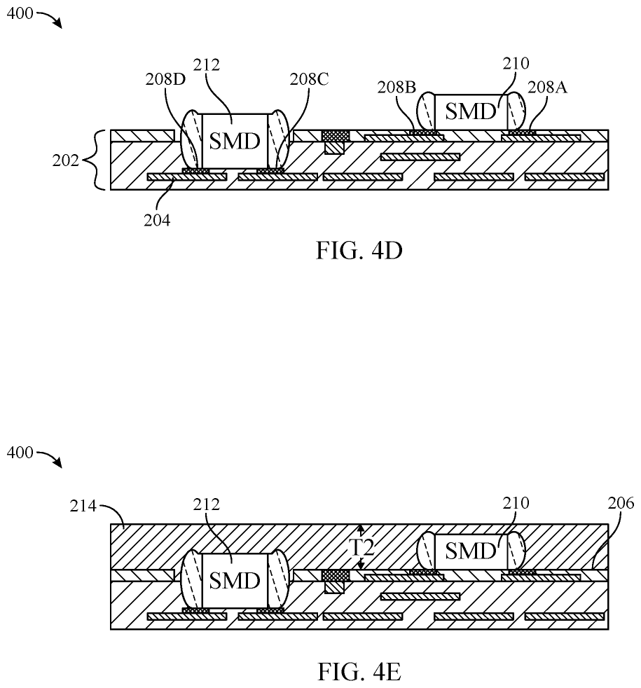

FIGS. 4A-4E depict example operations for fabricating an electronic device (e.g., similar to the electronic device 200B of FIG. 2B). As shown in FIG. 4A, the workpiece 400 may be a substrate 202 formed with the conductive elements 204 disposed within the metal layers 216, 218, 219 separated by the dielectric layers 203, 205, 207. The substrate 202 may be a laminate substrate, formed by laminating the metal layers one above another. Additionally, the solder resist layer 206 may be formed above the topmost metal layer 219. Furthermore, the substrate 202 may include one or more alignment vias 217 disposed within the dielectric layer 203. The solder resist layer 206 may be formed by depositing a solder resist material and subsequently removing (e.g., etching) the solder resist material according to a pattern prior to addition of the SMD(s), as further described herein.

As shown in FIG. 4B, a portion of the substrate 202 may be selectively etched to form the cavity 302. The cavity 302 may be shaped to receive the large SMD 212. The depth of the cavity 302 may be controlled such that a portion 209 of the dielectric layer 205 remains in the cavity. The cavity 302 may be rounded on the sides, as shown. Alternatively, sides of the cavity 302 may be relatively straight, concave, or any other suitable shape. Additionally, as depicted, holes 402, 404 may be formed in the remaining portion 209 of the dielectric layer 205. The holes 402, 404 may be formed to align with the terminals of the large SMD 212 and reach two of the conductive elements 204 within the metal layer 216.

As depicted in FIG. 4C solder paste for eventual solder areas 208A, 208B may be applied to holes within the solder resist layer 206, using the solder resist layer as a stencil. Likewise, solder paste for eventual solder areas 208C, 208D may be applied in the cavity 302 to the holes 402, 404 in the remaining portion 209 of the dielectric layer 205, such that the remaining portion acts as a stencil for the solder paste. The solder paste may be applied such that the eventual solder areas 208C, 208D after solder reflow are disposed above and electrically coupled to the conductive elements 204 within the metal layer 216, as shown.

As shown in FIG. 4D, the terminals of the small SMD 210 may be aligned with the solder paste in the eventual solder areas 208A, 208B. Furthermore, the terminals of the large SMD 212 may be aligned with the solder paste in the eventual solder areas 208C, 208D in the cavity 302 such that the large SMD 212 is partially inserted in the substrate 202. Once the large SMD 212 and the small SMD 210 are placed accordingly, the workpiece 400 may be heated, such that the solder paste is reflowed and the SMDs 210, 212 are electrically and mechanically coupled to the conductive elements 204 via the solder areas 208.

Then, the encapsulation material 214 may be formed above the solder resist layer 206 to cover the large SMD 212 and the small SMD 210, as illustrated in FIG. 4E. Furthermore, the encapsulation material 214 may be formed to have the thickness T2.

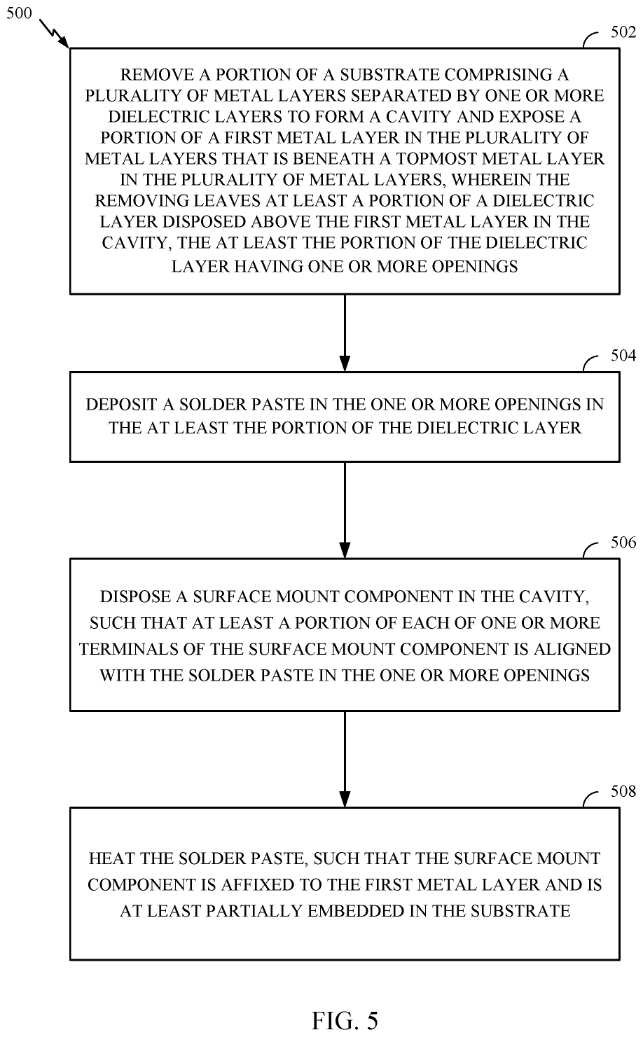

FIG. 5 is a block diagram of example operations 500 for fabricating an electronic device (e.g. the electronic device 200B, 200C, 200D, or 200G depicted in FIG. 2B, 2C, 2D, or 2G) with a partially embedded SMD, in accordance with certain aspects of the present disclosure. The operations 500 may be performed by a fabrication facility, for example.

The operations 500 may begin at block 502 with the facility removing a portion of a substrate (e.g., the substrate 202) comprising a plurality of metal layers (e.g., the metal layers 216, 218, 219) separated by one or more dielectric layers (e.g., dielectric layers 203, 205, 207) to form a cavity (e.g., the cavity 302) and expose a portion of a first metal layer (e.g., metal layer 216) in the plurality of metal layers that is beneath a topmost metal layer (e.g., the metal layer 219) in the plurality of metal layers. The removal of the portion of the substrate leaves at least a portion of a dielectric layer (e.g., remaining portion 209 of dielectric layer 205) disposed above the first metal layer in the cavity. The at least the portion of the dielectric layer has one or more openings (e.g., holes 402, 404). In certain aspects, the portion of the substrate is removed by etching the portion of the substrate. In some cases, a height of the at least the portion of the dielectric layer disposed above the first metal layer in the cavity is lower than a height of a remaining portion of the dielectric layer. Furthermore, in certain aspects, a height of the surface mount component is greater than a height of the substrate. In some cases, the portion of the substrate may be removed by using a laser. In certain aspects, the dielectric layer is composed of a pre-impregnated material. In some cases, an encapsulation material (e.g., the encapsulation material 214) is added above the substrate with the at least partially embedded surface mount component. In certain aspects, the substrate is a laminate substrate.

At block 504, the facility deposits a solder paste in the one or more openings in the at least the portion of the dielectric layer.

At block 506, the facility disposes a surface mount component (e.g., the large SMD 212) in the cavity, such that at least a portion of each of one or more terminals (e.g., terminals 298, 299) of the surface mount component is aligned with the solder paste in the one or more openings.

At block 508, the facility heats the solder paste, such that the surface mount component is affixed (e.g., electrically and mechanically coupled) to the first metal layer and is at least partially embedded in the substrate.

In certain aspects, the first metal layer is the bottommost metal layer (e.g., the metal layer 216) in the plurality of metal layers.

In certain aspects, one or more portions of a second metal layer (e.g., the metal layer 221) located above the first metal layer is exposed. In this case, the solder paste may be deposited by forming a stepped solder paste structure above the portion of the first metal layer and the one or more portions of the second metal layer. In certain aspects, the portion of the first metal layer and the one or more portions of the second metal layer are coupled together by one or more vias (e.g., vias 228), and the stepped solder paste structure is disposed adjacent to the one or more vias.

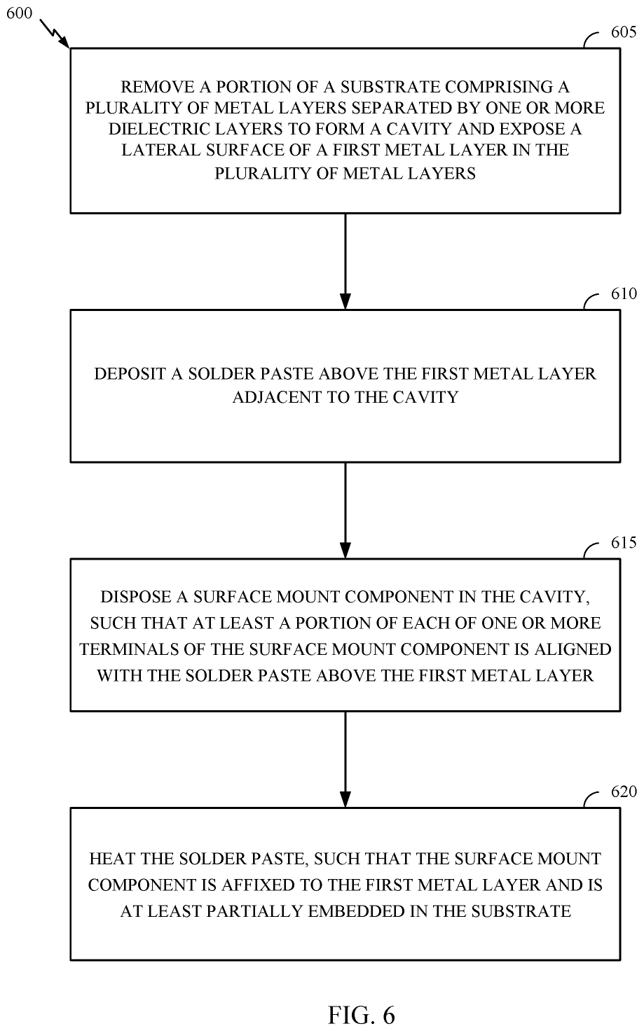

FIG. 6 is a block diagram of example operations 600 for fabricating an electronic device (e.g. the electronic device 200E, 200F, or 200G depicted in FIG. 2E, 2F, or 2G), in accordance with certain aspects of the present disclosure. The operations 600 may be performed by a fabrication facility, for example.

The operations 600 may begin at block 602 by removing a portion of a substrate (e.g., the substrate 202) comprising a plurality of metal layers (e.g., the metal layers 216, 218, 219) separated by one or more dielectric layers (e.g., the dielectric layers 203, 205, 207) to form a cavity (e.g., the cavity 302) and expose a lateral surface of a first metal layer in the plurality of metal layers. In certain aspects, the first metal layer is the topmost metal layer (e.g., metal layer 219) in the plurality of metal layers. At block 604, the facility deposits a solder paste above the first metal layer adjacent to the cavity.

At block 606, the facility disposes a surface mount component (e.g., the large SMD 212) in the cavity, such that at least a portion of each of one or more terminals of the surface mount component is aligned with the solder paste above the first metal layer. In certain aspects, a height of the surface mount component is greater than a height of the substrate. At block 608, the facility heats the solder paste, such that the surface mount component is affixed to the first metal layer and is at least partially embedded in the substrate.

According to certain aspects, the removal of the portion of the substrate at block 602 exposes one or more vias (e.g., the vias 228) adjacent to the cavity and coupled to the first metal layer. In certain aspects, the solder paste is deposited at block 604 by forming an L-shaped solder paste structure (e.g., L-shaped solder areas 208C, 208D) having a first portion above the first metal layer and having a second portion disposed adjacent to the one or more vias. For certain aspects, the removing at block 602 comprises exposing one or more portions of a second metal layer (e.g., metal layer 218) located below the first metal layer. In this case, the solder paste may be deposited at block 604 by forming a stepped solder paste structure above the portion of the first metal layer and the one or more portions of the second metal layer. In certain aspects, the portion of the first metal layer and the one or more portions of the second metal layer are coupled together by one or more vias (e.g., vias 228), and the stepped solder paste structure is disposed adjacent to the one or more vias.

Certain aspects of the present disclosure provide an electronic device. The electronic device generally includes a substrate (e.g., substrate 202) comprising a plurality of metal layers (e.g., metal layers 216, 218, 219) separated by one or more dielectric layers (e.g., dielectric layers 203, 205, 207). The substrate has a cavity (e.g., cavity 302) with a depth from an upper surface of the substrate to a first metal layer (e.g., metal layer 216) in the plurality of metal layers that is beneath a topmost metal layer (e.g., metal layer 219) in the plurality of metal layers. At least a portion of a dielectric layer (e.g., remaining portion 209 of dielectric layer 205) is disposed above the first metal layer in the cavity. The at least the portion of the dielectric layer has one or more openings (e.g., holes 402, 404). The electronic device also includes a surface mount component (e.g., the large SMD 212) disposed in the cavity above the at least the portion of the dielectric layer disposed above the first metal layer. Each of one or more terminals (e.g., terminals 298, 299) of the surface mount component is affixed with solder (e.g., solder areas 208C, 208D) to the first metal layer via the one or more openings in the at least the portion of the dielectric layer. The surface mount component is at least partially embedded in the substrate.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A method for fabricating an electronic device, comprising:
removing a portion of a substrate comprising a plurality of metal layers separated by one or more dielectric layers to form a cavity and expose a portion of a first metal layer in the plurality of metal layers that is beneath a topmost metal layer in the plurality of metal layers, wherein the removing leaves at least a portion of a dielectric layer disposed above the first metal layer in the cavity, the at least the portion of the dielectric layer having one or more openings;
depositing a solder paste in the one or more openings in the at least the portion of the dielectric layer;
disposing a surface mount component in the cavity, such that at least a portion of each of one or more terminals of the surface mount component is aligned with the solder paste in the one or more openings; and
heating the solder paste, such that the surface mount component is affixed to the first metal layer and is at least partially embedded in the substrate.

2. The method of claim 1, wherein the first metal layer is the bottommost metal layer in the plurality of metal layers.

3. The method of claim 1, wherein the removing comprises exposing one or more portions of a second metal layer located above the first metal layer.

4. The method of claim 3, wherein depositing the solder paste comprises forming a stepped solder paste structure above the portion of the first metal layer and the one or more portions of the second metal layer.

5. The method of claim 4, wherein the portion of the first metal layer and the one or more portions of the second metal layer are coupled together by one or more vias and wherein the stepped solder paste structure is disposed adjacent to the one or more vias.

6. The method of claim 1, wherein a height of the at least the portion of the dielectric layer disposed above the first metal layer in the cavity is lower than a height of a remaining portion of the dielectric layer.

7. The method of claim 1, wherein a height of the surface mount component is greater than a height of the substrate.

8. The method of claim 1, wherein removing the portion of the substrate comprises etching the portion of the substrate.

9. The method of claim 1, wherein removing the portion of the substrate comprises using a laser.

10. The method of claim 1, wherein the dielectric layer comprises a pre-impregnated material.

11. The method of claim 1, further comprising adding an encapsulation material above the substrate having the at least partially embedded surface mount component.

12. The method of claim 1, wherein the substrate comprises a laminate substrate.

13. A method for fabricating an electronic device, comprising:
removing a portion of a substrate comprising a plurality of metal layers separated by one or more dielectric layers to form a cavity and expose a lateral surface of a first metal layer in the plurality of metal layers;
depositing a solder paste above the first metal layer adjacent to the cavity;
disposing a surface mount component in the cavity, such that at least a portion of each of one or more terminals of the surface mount component is aligned with the solder paste above the first metal layer; and
heating the solder paste, such that the surface mount component is affixed to the first metal layer and is at least partially embedded in the substrate.

14. The method of claim 13, wherein the first metal layer is the topmost metal layer in the plurality of metal layers.

15. The method of claim 13, wherein the removing comprises exposing one or more vias adjacent to the cavity and coupled to the first metal layer.

16. The method of claim 15, wherein depositing the solder paste comprises forming an L-shaped solder paste structure having a first portion above the first metal layer and having a second portion disposed adjacent to the one or more vias.

17. The method of claim 15, wherein the removing comprises exposing one or more portions of a second metal layer located below the first metal layer.

18. The method of claim 17, wherein depositing the solder paste comprises forming a stepped solder paste structure above the portion of the first metal layer and the one or more portions of the second metal layer.

19. The method of claim 18, wherein the portion of the first metal layer and the one or more portions of the second metal layer are coupled together by one or more vias and wherein the stepped solder paste structure is disposed adjacent to the one or more vias.

20. An electronic device comprising:
a substrate comprising a plurality of metal layers separated by one or more dielectric layers, the substrate having a cavity with a depth from an upper surface of the substrate to a first metal layer in the plurality of metal layers that is beneath a topmost metal layer in the plurality of metal layers, wherein at least a portion of a dielectric layer is disposed above the first metal layer in the cavity and wherein the at least the portion of the dielectric layer has one or more openings; and
a surface mount component disposed in the cavity above the at least the portion of the dielectric layer disposed above the first metal layer, wherein each of one or more terminals of the surface mount component is affixed with solder to the first metal layer via the one or more openings in the at least the portion of the dielectric layer and wherein the surface mount component is at least partially embedded in the substrate.
